(19) United States
(12) Patent Application Publication
(10) Pub. No.: US 2011/0147786 A1
(43) Pub. Date: Jun. 23, 2011

(54) LIGHT-EMITTING DEVICE AND MANUFACTURING METHOD THEREOF

(76) Inventor: June O. Song, Seoul (KR)

(21) Appl. No.: 12/936,800

(22) PCT Filed: Apr. 8, 2009
(86) PCT No.: PCT/KR09/01824

§ 371 Date: Feb. 25, 2011

(30) Foreign Application Priority Data
Apr. 8, 2008 (KR) 10-2008-0032406
Apr. 8, 2008 (KR) 10-2008-0032407

(51) Int. Cl. H01L 33/42

(52) U.S. Cl. 257/99; 438/22; 257/E33.012; 257/E33.064

(57) ABSTRACT

Disclosed is a light emitting device and a method of manufacturing the same. The light emitting device includes a first conductive semiconductor layer, an active layer over the first conductive semiconductor layer, a second conductive semiconductor layer over the active layer, a current spreading layer over the second conductive semiconductor layer, a first electrode layer over the first conductive semiconductor, and a second electrode layer over the current spreading layer.

### TECHNICAL FIELD

The embodiment relates to a light emitting device and a method of manufacturing the same.

### BACKGROUND ART

Recently, a light emitting diode (LED) is spotlighted as a light emitting device. Since the LED can convert electric energy into light energy with high efficiency and long life span of about 5 years or more, the LED can remarkably reduce the energy consumption and repair and maintenance cost. In this regard, the LED is spotlighted in the next-generation lighting field.

Such an LED is prepared as a light emitting semiconductor layer including a first conductive semiconductor layer, an active layer and a second conductive semiconductor layer, in which the active layer generates light according to current applied thereto through the first and second conductive semiconductor layers.

Meanwhile, in the LED, since the second conductive semiconductor layer has relatively high sheet resistance due to low carrier concentration and mobility, a transparent current spreading layer is required to form an ohmic contact interface with respect to a top surface of the second conductive semiconductor layer.

When the transparent current spreading layer including ITO or ZnO is formed on the second conductive semiconductor layer to form an ohmic contact interface, the transparent current spreading layer may form a schottky contact interface instead of the ohmic contact interface due to subsequent processes such as deposition and annealing processes.

Therefore, a scheme to bond the transparent current spreading layer to the second conductive semiconductor layer has been researched and studied. However, when the current spreading layer is simply bonded to the second conductive semiconductor layer, since the current spreading layer cannot be formed at a thin thickness, superior electrical conductivity cannot be represented, and many problems may occur in the bonding process due to the difference in thermal expansion coefficients between the second conductive semiconductor layer and the current spreading layer.

### DISCLOSURE

### Technical Problem

The embodiment provides a light emitting device having a new structure and a method of manufacturing the same.

The embodiment provides a light emitting device having improved electrical characteristics and a method of manufacturing the same.

The embodiment provides a light emitting device having improved light efficiency and a method of manufacturing the same.

### Technical Solution

According to the embodiment, a light emitting device includes a first conductive semiconductor layer, an active layer over the first conductive semiconductor layer, a second conductive semiconductor layer over the active layer, a current spreading layer over the second conductive semiconductor layer, a first electrode layer over the first conductive semiconductor, and a second electrode layer over the current spreading layer.

According to the embodiment, a method of manufacturing a light emitting device includes preparing a first structure in which a first conductive semiconductor layer, an active layer, and a second conductive semiconductor layer are formed on a growth substrate,

preparing a second structure in which a current spreading layer is formed on a temporary substrate, forming a complex structure by bonding the second conductive semiconductor layer of the first structure to the current spreading layer of the second structure through a wafer bonding process, separating the temporary substrate from the complex structure, forming a first electrode layer on the first conductive semiconductor layer, and forming a second electrode layer on the current spreading layer.

According to the embodiment, a method of manufacturing a light emitting device includes preparing a first structure in which a first conductive semiconductor layer, an active layer, and a second conductive semiconductor layer are formed on a growth substrate, preparing a second structure in which a current spreading layer is formed on a temporary substrate, preparing a third structure by using a transparent bonding layer, forming a complex structure by bonding the second conductive semiconductor layer of the first structure to the current spreading layer of the second structure through a wafer bonding process while interposing the transparent bonding layer between the second conductive semiconductor layer and the current spreading layer, separating the temporary substrate from the complex structure, forming a first electrode layer on the first conductive semiconductor layer, and forming a second electrode layer on the current spreading layer.

### Advantageous Effects

The embodiment can provide a light emitting device having a new structure and a method of manufacturing the same.

The embodiment can provide a light emitting device having improved electrical characteristics and a method of manufacturing the same.

The embodiment can provide a light emitting device having improved light efficiency and a method of manufacturing the same.

### DESCRIPTION OF DRAWINGS

FIGS. 1 to 6 are sectional views showing a light emitting device and a method of manufacturing the same according to a first embodiment; and

FIGS. 7 to 13 are sectional views showing a light emitting device and a method of manufacturing the same according to a second embodiment.

### BEST MODE

### Mode for Invention

In the description of the embodiments, it will be understood that, when a layer (or film), a region, a pattern, or a structure is referred to as being “on” or “under” another substrate, another layer (or film), another region, another pad, or another pattern, it can be “directly” or “indirectly” on the other substrate, layer (or film), region, pad, or pattern, or one or more intervening layers may also be present. Such a position of the layer has been described with reference to the drawings.

The thickness and size of each layer shown in the drawings may be exaggerated, omitted or schematically drawn for the purpose of convenience or clarity. In addition, the size of elements does not utterly reflect an actual size.

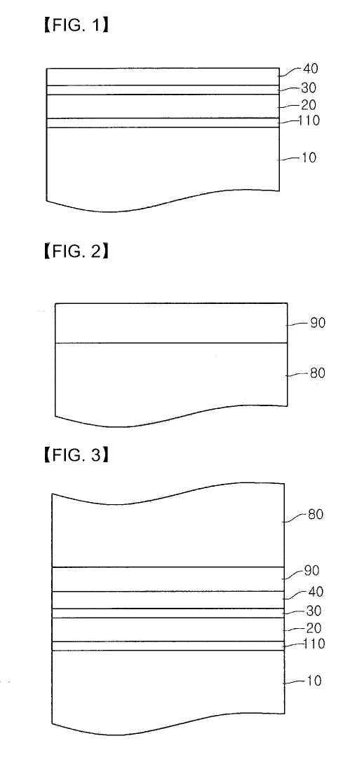

FIGS. 1 to 6 are sectional views showing a light emitting device and a method of manufacturing the same according to a first embodiment.

Referring to FIG. 6, a buffer layer 110 is formed on a growth substrate 10, and a light emitting semiconductor layer including a first conductive semiconductor layer 20, an active layer 30, and a second conductive semiconductor layer 40 is formed on the buffer layer 110. The light emitting semiconductor layer is partially removed through a MESA etching process, so that a portion of the first conductive semiconductor layer 20 is exposed upward.

A current spreading layer 90 is bonded to the second conductive semiconductor layer 40. A first electrode layer 70 is formed on the first conductive semiconductor layer 20, and a second electrode layer 60 is formed on the current spreading layer 90.

In more detail, for example, the growth substrate 10 may include one selected from the group consisting of Al₂O₃, SiC, Si, AlN, GaN, AlGaN, glass, and GaAs.

The buffer layer 110 is formed on the growth substrate 10 for the purpose of lattice match before the first conductive semiconductor layer 20 is grown. For example, the buffer layer 110 may include at least one selected from the group consisting of InGaN, AlN, SiC, SiCN, and GaN.

The light emitting semiconductor layer including the first conductive semiconductor layer 20, the active layer 30, and the second conductive semiconductor layer 40 may include a group III nitride-based semiconductor material. For example, the first conductive semiconductor layer 20 may include a gallium nitride layer including N type impurities such as Si, and the second conductive semiconductor layer 40 may include a gallium nitride layer including P type impurities such as Mg or Zn. In addition, the active layer 30 generates light through the recombination of electrons and holes. The active layer 30 may include one selected from the group consisting of InGaN, AlGaN, GaN, and AlInGaN. A wavelength of light emitted from the light emitting device is determined according to the type of a material constituting the active layer 30.

The active layer 30 and the second conductive semiconductor layer 40 are formed on a portion of the first conductive semiconductor layer 20. In other words, the portion of the first conductive semiconductor layer 20 vertically overlaps with the active layer 30.

Although not shown, an interface modification layer may be additionally formed on the second conductive semiconductor layer 40.

The interface modification layer may include a superlattice structure, one of InGaN, GaN, AlInN, AlN, InN, and AlGaN doped with first conductive impurities, one of InGaN, GaN, AlInN, AlN, InN, and AlGaN doped with second conductive impurities, or one of group III nitride-based elements having nitrogen-polar surfaces. In particular, the interface modification layer having the superlattice structure may include nitride or carbon nitride including group II, III, or IV elements.

The current spreading layer 90 is bonded to the second conductive semiconductor layer 40. The current spreading layer 90 may include one of electrical conductive oxide, electrical conductive nitride, and electrical conductive nitrogen oxides having high light transmittance.

For example, the electrical conductive oxide may include one of ITO, SnO₂, In₂O₃, ZnO, and MgZnO, and the electrical conductive nitride may include one of TiN, CrN, InGaN, GaN, InN, AlGaN, and AlInGaN. The electrical conductive nitrogen oxide may include one of ITON, ZnON, and TiON. In addition, the current spreading layer 90 may be doped with impurities in order to lower resistance and improve electrical conductivity.

The current spreading layer 90 may have a single layer structure or a multi-layer structure including an electrical conductive thin film having electrical resistance of 10⁻² Ωcm or less. The current spreading layer 90 may include a single crystal structure with a non-polar surface tetragonal system, a positive-polar surface hexagonal system, a negative-polar surface hexagonal system, or a hybrid-polar-surface hexagonal system. In addition, the current spreading layer 90 may include an electrical conductive thin film having a poly-crystal structure or an amorphous structure.

In addition, the current spreading layer 90 may have a superior electrical conducting or semi-conducting property regardless of charges of holes or electrons serving as majority carriers.

Although not shown, a light extracting structure having a concave-convex pattern may be formed on a top surface of the current spreading layer 90 such that light emitted from the active layer 30 can be effectively extracted.

A functional thin film layer, which includes electrical conductive heterogeneous materials, luminescent materials, non-reflective materials, or light filtering materials, may be formed on the current spreading layer 90. Before the functional thin film layer is formed, a concave-convex structure may be formed on the current spreading layer 90. A concave-convex structure may be formed on a top surface of the functional thin film layer.

The first electrode layer 70 forms an ohmic contact interface with respect to the first conductive semiconductor layer 20, and the second electrode layer 60 forms a schottky contact interface with respect to the current spreading layer 90.

Hereinafter, a method of manufacturing the light emitting device according to the first embodiment will be described with reference to FIGS. 1 to 6.

Referring to FIG. 1, the buffer layer 110 is formed on the growth substrate 10, and the light emitting semiconductor layer including the first conductive semiconductor layer 20, the active layer 30, and the second conductive semiconductor layer 40 is formed on the buffer layer 110, thereby preparing a first structure. Although not shown, the interface modification layer may be further formed on the second conductive semiconductor layer 40

Referring to FIG. 2, the current spreading layer 90 is formed on a temporary substrate 80, thereby preparing a second structure.

For example, the temporary substrate 80 may include one selected from the group consisting of sapphire, glass, aluminum nitride, SiC, ZnO, GaAs, Si, Ge, and SiGe that are optically transparent.

Although not shown, a sacrificial separation layer (not shown) may be formed between the temporary substrate 80 and the current spreading layer 90.

The sacrificial separation layer may include one of group II-VI compounds including ZnO, which is subject to the thermal-chemical decomposition reaction as laser beam is irradiated thereto; group III-V compounds including GaN; ITO; PZT; and SU-8. In addition, the sacrificial separation layer may include one of Al, Au, Ag, Cr, Ti, In, Sn, Zn, Pd, Pt, Ni, Mo, W, CrN, TiN, In₂O₃, SnO₂, NiO, RuO₂, IrO₂, SiO₂, and SiNₓ, which are rapidly dissolved in a wet solution.

Referring to FIG. 3, the first and second structures are bonded to each other through a direct wafer bonding process. In other words, the current spreading layer 90 is bonded to the second conductive semiconductor layer 40, thereby forming a complex structure.

A process of forming the complex structure may include a wafer bonding process performed at the temperature of about 900° C. or less under hydrostatic pressure.

In order to form an ohmic contact interface between the second conductive semiconductor layer 40 and the current spreading layer 90, before the complex structure is formed, an annealing process may be performed with respect to the current spreading layer 90 and the second conductive semiconductor layer 40 at a proper temperature and a gas atmosphere, or a surface-treatment process may be performed with respect to the current spreading layer 90 and the second conductive semiconductor layer 40 by using solution or plasma. In addition, after the complex structure has been formed, the annealing process or the surface-treatment process may be performed.

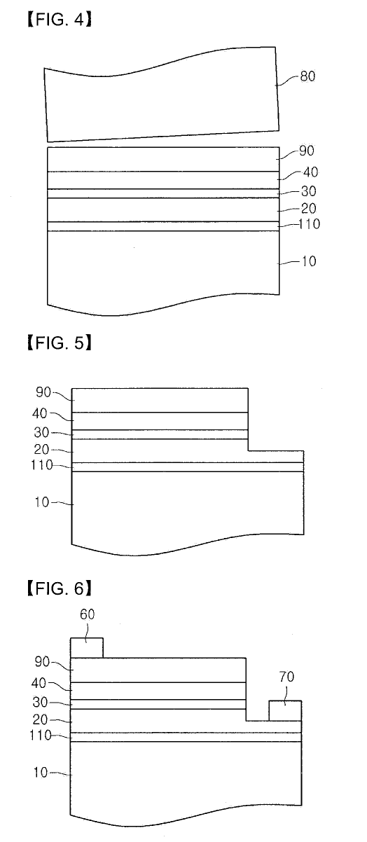

Referring to FIG. 4, the temporary substrate 80 is separated from the complex structure.

The temporary substrate 80 may be separated from the complex structure through at least one of a CLO (Chemical Lift Off) process, a CMP (Chemical Mechanical Polishing) process and a LLO (Laser Lift Off) process.

A scheme of separating the temporary substrate 80 may be selected according to the type of the temporary substrate 80. When the sacrificial separation layer (not shown) is formed between the temporary substrate 80 and the current spreading layer 90, the sacrificial separation layer assists the separation of the temporary substrate 80.

Referring to FIG. 5, the current spreading layer 90, the second conductive semiconductor layer 40, the active layer 30, and the first conductive semiconductor layer 20 are selectively etched such that the first conductive semiconductor layer 20 can be partially exposed.

According to another embodiment, when the second structure is prepared, after the current spreading layer 90 having the size shown in FIG. 5 is formed, the complex structure as shown in FIG. 3 is formed, and then the temporary substrate 80 may be separated from the complex structure.

Although not shown, a light extracting structure having a concave-convex pattern may be formed on the top surface of the current spreading layer 90 such that light emitted from the active layer 30 can be effectively extracted, or a functional thin film layer (not shown) may be additionally formed on the current spreading layer 90.

Referring to FIG. 6, the first electrode layer 70 is formed on the first conductive semiconductor layer 20, and the second electrode layer 60 is formed on the current spreading layer 90.

Therefore, the light emitting device according to the first embodiment can be manufactured.

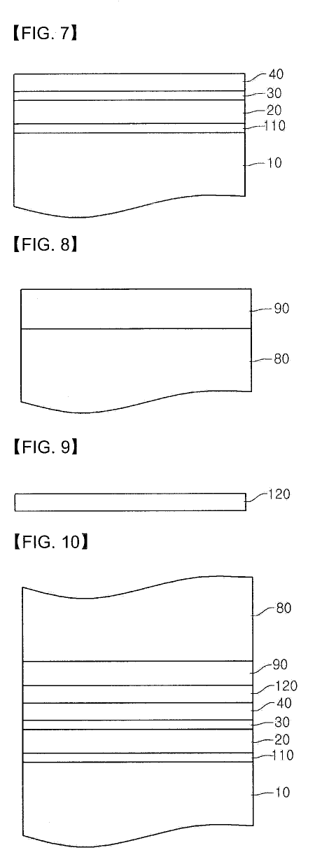

FIGS. 7 to 13 are sectional views showing a light emitting device and a method of manufacturing the same according to a second embodiment.

Referring to FIG. 13, the buffer layer 110 is formed on the growth substrate 10, and the light emitting semiconductor layer including the first conductive semiconductor layer 20, the active layer 30, and the second conductive semiconductor layer 40 is formed on the buffer layer 110. The light emitting semiconductor layer is partially removed through a MESA etching process, so that the first conductive semiconductor layer 20 is exposed upward.

A transparent bonding layer 120 and the current spreading layer 90 are bonded to the second conductive semiconductor layer 40. The first electrode layer 70 is formed on the first conductive semiconductor layer 20, and the second electrode layer 60 is formed on the current spreading layer 90.

In more detail, for example, the growth substrate 10 may include one selected from the group consisting of Al₂O₃, SiC, Si, AlN, GaN, AlGaN, glass, and GaAs.

The buffer layer 110 is formed on the growth substrate 10 for the purpose of lattice match before the first conductive semiconductor layer 20 is grown. For example, the buffer layer 110 may include at least one selected from the group consisting of InGaN, AlN, SiC, SiCN, and GaN.

The light emitting semiconductor layer including the first conductive semiconductor layer 20, the active layer 30, and the second conductive semiconductor layer 40 may include a group III nitride-based semiconductor material. For example, the first conductive semiconductor layer 20 may include a gallium nitride layer including N type impurities such as Si, and the second conductive semiconductor layer 40 may include a gallium nitride layer including P type impurities such as Mg or Zn. In addition, the active layer 30 generates light through the recombination of electrons and holes. The active layer 30 may include one selected from the group consisting of InGaN, AlGaN, GaN, and AlInGaN. A wavelength of light emitted from the light emitting device is determined according to the type of a material constituting the active layer 30.

The active layer 30 and the second conductive semiconductor layer 40 are formed on the portion of the first conductive semiconductor layer 20. In other words, the portion of the first conductive semiconductor layer 20 vertically overlaps with the active layer 30.

Although not shown, the interface modification layer may be additionally formed on the second conductive semiconductor layer 40.

The interface modification layer may include a superlattice structure, one of InGaN, GaN, AlInN, AlN, InN, and AlGaN doped with first conductive impurities, one of InGaN, GaN, AlInN, AlN, InN, and AlGaN doped with second conductive impurities, or one of group III nitride-based elements having nitrogen-polar surfaces. In particular, the interface modification layer having the superlattice structure may include nitride or carbon nitride including group II, III, or IV elements.

The transparent bonding layer 120 may include electrical conductive materials having high light transmittance. For example, the transparent bonding layer 120 may have a single layer structure or a multi-layer structure including at least one selected from the group consisting of ITO, ZnO, IZO, ZITO, In₂O₃, SnO₂, Sn, Zn, In, Ni, Au, Ru, Ir, NiO, Ag, Pt, Pd, PdO, IrO₂, RuO₂, Ti, TiN, Cr, and CrN.

The transparent bonding layer 120 enhances mechanical bonding strength between the second conductive semiconductor layer 40 and the current spreading layer 90, and forms an ohmic contact interface with respect to the second conductive semiconductor layer 40.

The current spreading layer 90 is bonded to the second conductive semiconductor layer 40 through the transparent bonding layer 120. The current spreading layer 90 may include one of electrical conductive oxide, electrical conductive nitride, and electrical conductive nitrogen oxide having high light transmittance.

For example, the electrical conductive oxide may include one of ITO, SnO₂, In₂O₃, ZnO, and MgZnO, and the electrical conductive nitride may include one of TiN, CrN, InGaN, GaN, InN, AlGaN, and AlInGaN. The electrical conductive nitrogen oxide may include one of ITON, ZnON, and TiON. In addition, the current spreading layer 90 may be doped with impurities in order to reduce resistance and improve electrical conductivity.

The current spreading layer 90 may have a single layer structure or a multi-layer structure including an electrical conductive thin film having electrical resistance of 10⁻² Ωcm or less. The current spreading layer 90 may include a single crystal structure with a non-polar surface tetragonal system, a positive-polar surface hexagonal system, a negative-polar surface hexagonal system, or a hybrid-polar-surface hexagonal system. In addition, the current spreading layer 90 may include an electrical conductive thin film having a poly-crystal structure or an amorphous structure.

In addition, the current spreading layer 90 may have a superior electrical conducting or semi-conducting property regardless of charges of holes or electrons serving as majority carriers.

Although not shown, the light extracting structure having a concave-convex pattern may be formed on the top surface of the current spreading layer 90 such that light emitted from the active layer 30 can be effectively extracted.

The functional thin film layer, which includes electrical conductive heterogeneous materials, luminescent materials, non-reflective materials, or light filtering materials, may be formed on the current spreading layer 90. Before the functional thin film layer is formed, a concave-convex structure may be formed on the current spreading layer 90. A concave-convex structure may be formed on a top surface of the functional thin film layer.

The first electrode layer 70 forms an ohmic contact interface with respect to the first conductive semiconductor layer 20, and the second electrode layer 60 forms a schottky contact interface with respect to the current spreading layer 90.

Hereinafter, the method of manufacturing the light emitting device according to the second embodiment will be described with reference to FIGS. 7 to 13.

Referring to FIG. 7, the buffer layer 110 is formed on the growth substrate 10, and the light emitting semiconductor layer including the first conductive semiconductor layer 20, the active layer 30, and the second conductive semiconductor layer 40 is formed on the buffer layer 110, thereby preparing the first structure. Although not shown, the interface modification layer may be additionally formed on the second conductive semiconductor layer 40.

Referring to FIG. 8, the current spreading layer 90 is formed on the temporary substrate 80, thereby preparing the second structure.

For example, the temporary substrate 80 may include one selected from the group consisting of sapphire, glass, aluminum nitride, SiC, ZnO, GaAs, Si, Ge, and SiGe that are optically transparent.

Although not shown, the sacrificial separation layer (not shown) may be formed between the temporary substrate 80 and the current spreading layer 90.

The sacrificial separation layer may include one of group II-VI compounds including ZnO, which is subject to the thermal-chemical decomposition reaction as laser beam is irradiated thereto; group III-V compounds including GaN; ITO; PZT; and SU-8. In addition, the sacrificial separation layer may include one of Al, Au, Ag, Cr, Ti, In, Sn, Zn, Pd, Pt, Ni, Mo, W, CrN, TiN, In₂O₃, SnO₂, NiO, RuO₂, IrO₂, SiO₂, and SiNₓ, which are rapidly dissolved in a wet solution.

Referring to FIG. 9, a third structure is prepared by using the transparent bonding layer 120.

Referring to FIG. 10, the first and second structures are bonded to each other through the third structure by using an indirect wafer bonding process. The current spreading layer 90 is bonded to the transparent bonding layer 120, and the transparent bonding layer 120 is bonded to the second conductive semiconductor layer 40, thereby forming the complex structure.

The process of forming the complex structure may include a wafer bonding process performed at the temperature of about 900° C. or less under hydrostatic pressure.

In order to form an ohmic contact interface between the second conductive semiconductor layer 40 and the current spreading layer 90, before the complex structure is formed, an annealing process may be performed with respect to the current spreading layer 90 and the second conductive semiconductor layer 40 at a proper temperature and a proper gas atmosphere, or a surface-treatment process may be performed with respect to the current spreading layer 90 and the second conductive semiconductor layer 40 by using solution or plasma. In addition, after the complex structure has been formed, the annealing process or the surface-treatment process may be performed.

Referring to FIG. 11, the temporary substrate 80 is separated from the complex structure.

The temporary substrate 80 may be separated from the complex structure through at least one of a CLO (Chemical Lift Off) process, a CMP (Chemical Mechanical Polishing) process and a LLO (Laser Lift Off) process.

A scheme of separating the temporary substrate 80 may be selected according to the type of the temporary substrate 80. When the sacrificial separation layer (not shown) is formed between the temporary substrate 80 and the current spreading layer 90, the sacrificial separation layer assists the separation of the temporary substrate 80.

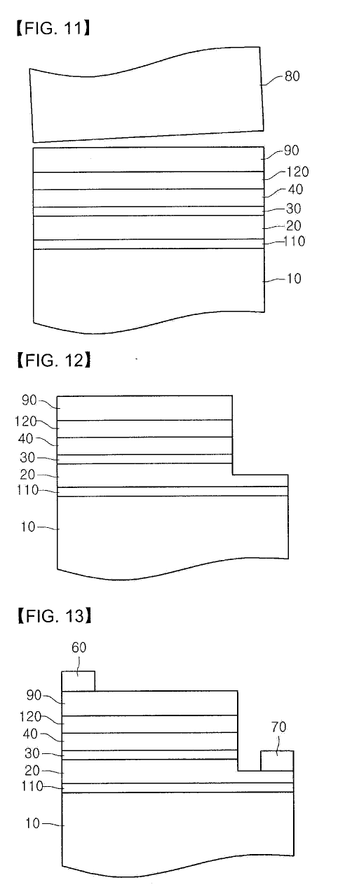

Referring to FIG. 12, the current spreading layer 90, the transparent bonding layer 120, the second conductive semiconductor layer 40, the active layer 30, and the first conductive semiconductor layer 20 are selectively etched such that the first conductive semiconductor layer 20 can be partially exposed.

According to another embodiment, when the second and third structures are prepared, after the current spreading layer 90 and the transparent bonding layer 120 having the size shown in FIG. 12 are formed, the complex structure as shown in FIG. 10 is formed, and then the temporary substrate 80 is separated from the complex structure.

Although not shown, the light extracting structure having a concave-convex pattern may be formed on the top surface of the current spreading layer 90 such that light emitted from the active layer 30 can be effectively extracted, or the functional thin film layer (not shown) may be additionally formed on the current spreading layer 90.

Referring to FIG. 13, the first electrode layer 70 is formed on the first conductive semiconductor layer 20, and the second electrode layer 60 is formed on the current spreading layer 90.

Therefore, the light emitting device according to the second embodiment can be manufactured.

According to the method of manufacturing the light emitting device of the embodiments, the current spreading layer 90 is bonded to the top surface of the second conductive semiconductor layer 40 through a direct wafer bonding scheme or an indirect wafer bonding scheme. Accordingly, an ohmic contact interface may be formed between the second conductive semiconductor layer 40 and the current spreading layer 90.

According to the method of manufacturing the light emitting device of the embodiments, since the current spreading layer 90 is shifted to the second conductive semiconductor layer 40 by using the temporary substrate 80, even if the current spreading layer 90 is formed at a thin thickness, the current spreading layer 90 is not damaged or destroyed in the bonding process, and can have high electrical conductivity.

According to the method of manufacturing the light emitting device of the embodiments, in the bonding process of the current spreading layer 90, the growth substrate 10 is arranged in opposite to the temporary substrate 80 while interposing the current spreading layer 90 between the growth substrate 10 and the temporary substrate 80, so that the destruction or damage of the current spreading layer 90 caused by the difference in the thermal expansion coefficients between the growth substrate 10 and the current spreading layer 90 can be reduced. In this case, the temporary substrate 80 may have a thermal expansion coefficient approximating that of the growth substrate 10.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### INDUSTRIAL APPLICABILITY

The embodiments are applicable to a light emitting device used as a light source.

1. A light emitting device comprising:
a first conductive semiconductor layer;
an active layer over the first conductive semiconductor layer;
a second conductive semiconductor layer over the active layer;
a current spreading layer over the second conductive semiconductor layer;
a first electrode layer over the first conductive semiconductor; and
a second electrode layer over the current spreading layer.

2. The light emitting device of claim 1, further comprising a transparent bonding layer between the second conductive semiconductor layer and the current spreading layer.

3. The light emitting device of claim 1, further comprising a growth substrate under the first conductive semiconductor layer.

4. The light emitting device of claim 1, wherein the current spreading layer includes one selected from the group consisting of electrical conductive oxide, electrical conductive nitride, and electrical conductive nitrogen oxide having light transmittance.

5. The light emitting device of claim 4, wherein the electrical conductive oxide includes one selected from the group consisting of ITO, SnO₂, In₂O₃, ZnO, and MgZnO, the electrical conductive nitride includes one selected from the group consisting of TiN, CrN, InGaN, GaN, InN, AlGaN, and AlInGaN, and the electrical conductive nitrogen oxide includes one selected from the group consisting of ITON, ZnON, and TiON.

6. The light emitting device of claim 2, wherein the transparent bonding layer has a single layer structure or a multi-layer structure including at least one selected from the group consisting of ITO, ZnO, IZO, ZITO, In₂O₃, SnO₂, Sn, Zn, In, Ni, Au, Ru, Ir, NiO, Ag, Pt, Pd, PdO, IrO₂, RuO₂, Ti, TiN, Cr, and CrN.

7. A method of manufacturing a light emitting device, the method comprising:
preparing a first structure in which a first conductive semiconductor layer, an active layer, and a second conductive semiconductor layer are formed on a growth substrate;
preparing a second structure in which a current spreading layer is formed on a temporary substrate;
forming a complex structure by bonding the second conductive semiconductor layer of the first structure to the current spreading layer of the second structure through a wafer bonding process;
separating the temporary substrate from the complex structure;
forming a first electrode layer on the first conductive semiconductor layer; and
forming a second electrode layer on the current spreading layer.

8. The method of claim 7, further comprising exposing the first conductive semiconductor layer by selectively removing the second conductive semiconductor layer, the active layer, and the first conductive semiconductor layer.

9. The method of claim 7, further comprising forming a sacrificial separation layer on the temporary substrate before the current spreading layer is formed.

10. The method of claim 7, wherein the current spreading layer includes one selected from the group consisting of electrical conductive oxide, electrical conductive nitride, and electrical conductive nitrogen oxide having light transmittance.

11. A method of manufacturing a light emitting device, the method comprising:
preparing a first structure in which a first conductive semiconductor layer, an active layer, and a second conductive semiconductor layer are formed on a growth substrate;
preparing a second structure in which a current spreading layer is formed on a temporary substrate;
preparing a third structure by using a transparent bonding layer;
forming a complex structure by bonding the second conductive semiconductor layer of the first structure to the current spreading layer of the second structure through a wafer bonding process while interposing the transparent bonding layer between these second conductive semiconductor layer and the current spreading layer;
separating the temporary substrate from the complex structure;
forming a first electrode layer on the first conductive semiconductor layer; and
forming a second electrode layer on the current spreading layer.

12. The method of claim 11, further comprising exposing the first conductive semiconductor layer by selectively removing the second conductive semiconductor layer, the active layer, and the first conductive semiconductor layer.

13. The method of claim 11, further comprising forming a sacrificial separation layer on the temporary substrate before the current spreading layer is formed.

14. The method of claim 11, wherein the current spreading layer includes one selected from the group consisting of electrical conductive oxide, electrical conductive nitride, and electrical conductive nitrogen oxide having light transmittance.

15. The method of claim 11, wherein the transparent bonding layer has a single layer structure or a multi-layer structure including at least one selected from the group consisting of ITO, ZnO, IZO, ZITO, In₂O₃, SnO₂, Sn, Zn, In, Ni, Au, Ru, Ir, NiO, Ag, Pt, Pd, PdO, IrO₂, RuO₂, Ti, TiN, Cr, and CrN.
